(19) United States
(12) Patent Application Publication
(10) Pub. No.: US 2009/0184311 A1
(43) Pub. Date: Jul. 23, 2009

(54) Nanowire placement by electrodeposition

(76) Inventor: Dan Steinberg, Blacksburg, VA (US)

Correspondence Address: Dan Steinberg, 1507 Glade Road, Blacksburg, VA, 24060, US

(21) Appl. No.: 12/291,640

(22) Filed: Nov. 12, 2008

Related U.S. Application Data
(63) Continuation-in-part of application No. 12/228,840, filed on Aug. 18, 2008, now abandoned.
(60) Provisional application No. 60/965,863, filed on Aug. 23, 2007.
(60) Provisional application No. 61/124,912, filed on Apr. 21, 2008.

(51) Int. Cl. H01L 33/00; H01L 21/36; H01L 31/0352; H01L 29/00

(52) U.S. Cl. 257/9; 438/497; 257/466; 257/623; 257/E21.461; 257/E33.005; 257/E31.032; 257/E29.001; 977/762

(57) ABSTRACT

Electrodeposition is used to deposit nanowires in a controlled fashion with accurate placement and orientation. A substrate is provided with a mesa having electrically conductive sidewalls. The substrate is immersed in an electroplating solution having a dispersion of nanowires, and metal is electroplated onto the sidewalls of the mesa. During electrodeposition, nanowires are incorporated and partially embedded in the deposited metal film. The nanowires will tend to be parallel with the substrate. Additionally electrodes can be deposited to provide electrical contact with the free ends of the nanowires. In this way, electrical connections can be provided to nanowires in a controlled, reproducible manner. The deposited nanowires can be used in a multitude of devices.

### RELATED APPLICATIONS

The present application claims the benefit of priority from provisional application 60/965,863, filed on Aug. 23, 2007 and provisional application 61/124,912 filed on Apr. 21, 2008, both of which are hereby incorporated by reference in their entirety. Also, the present application claims priority from copending patent application Ser. No. 12/228,840 filed on Aug. 18, 2008, which is also hereby incorporated by reference.

### FIELD OF THE INVENTION

The present invention relates generally to nanometer scale devices, and more particularly to methods for assembling nanowire devices and structures.

### BACKGROUND OF THE INVENTION

Nanowires are nanoscale filaments of material, typically less than 100 nanometers wide and 1-100 microns long. Due to their 1-dimensional shape, nanowires often exhibit unusual quantum mechanical and electronic properties. Nanowires can be made of semiconductors, ceramics, metals, glasses, polymers, or carbon for example.

Semiconductor nanowires in particular have attractive electronic properties such as high charge carrier mobility, light sensitivity, chemical sensitivity, and very low defect density. Semiconductor nanowires can therefore be used to fabricate high performance electronic switches, transistors, sensors and optoelectronic devices.

Nanowires can be made by several different methods such as the well known vapor-liquid-solid (VLS) method, template electroplating, solution growth or chemical vapor deposition. Structured nanowires can be fabricated with junctions, core/shell coatings and other useful features.

However, fabricating useful nanowire devices requires the accurate placement and in-plane rotational orientation of nanowires on a target substrate. For example, orientation of nanowires can be controlled by liquid flow. In the liquid flow method nanowires are suspended and dispersed in a liquid, which is flowed over the substrate. Nanowires depositing on the substrate will tend to have an in-plane orientation parallel with the direction of flow. However, this method cannot control the longitudinal position of the nanowires, only their rotational orientation. Consequently, the flow orientation method is not suitable for fabricating some kinds of nanowire devices.

### DESCRIPTION OF THE FIGURES

FIG. 1 shows a nanowire device according to the present invention.

FIG. 2 shows a nanowire device with a second electrode for making electrical contact to a free end of the nanowires.

FIG. 3 shows a top view of the nanowire device of FIG. 2.

FIGS. 4a-4c illustrate a method for depositing nanowires according to the present invention.

FIGS. 5a-5b illustrate a method for improving nanowire alignment by fluid flow.

FIG. 6 shows a nanowire device having two groups of nanowires in contact.

FIG. 7 shows a nanowire device having two groups of orthogonal nanowires in contact

FIG. 8 shows a nanowire device having a semiconductor or active layer disposed under the nanowires.

FIG. 9 shows a nanowire device having a gate electrode.

FIG. 10 shows a nanowire device having a bridge contact for providing low resistance electrical contact to the nanowires.

FIG. 11 shows a nanowire device integrated on an integrated circuit.

FIG. 12 shows a nanowire with highly doped ends.

FIG. 13 shows a nanowire device with a symmetrical nanowire.

FIGS. 14a-14b show a nanowire device having a mesa with a tunnel, with nanowire disposed in the tunnel.

FIG. 15 shows an alternative electrical circuit for depositing nanowires according to one embodiment of the present invention.

FIG. 16 shows an embodiment in which the mesa is disposed in a trench.

FIG. 17 shows an embodiment in which the mesa and second electrode are interdigitated.

### DETAILED DESCRIPTION

### Definitions

Nanowire: any elongated, wire-like microscopic material with a width less than about 500 nm or 100 nm, and length/width ratio of at least 10, 100 or 1000. Typically, nanowires will have a width of about 10-100 nanometers, and a length of about 1-25 microns. Nanowires can be made of conductors (e.g. metals), semiconductors, ceramics, polymers, or carbon (carbon nanotubes) for example.

The present invention provides a method for depositing nanowires with at least partially controlled orientation and position. The nanowires are deposited on a substrate in an electroplating process that leaves the nanowires approximately horizontal to the substrate and partially embedded in an electrodeposited metal film. The electroplated metal film can provide an electrical connection to the embedded nanowire. In the present method, a mesa is provided on a substrate. The mesa has an electrically conductive sidewall, and optionally has an electrically insulating top surface. The mesa and substrate are immersed in an electrolyte bath containing a suspension of nanowires, and an electrodepositable material (e.g. metal). When metal is electrodeposited (electroplated) on the mesa sidewall, nanowires are co-deposited with the metal. An electric field within a depletion/diffusion layer surrounding the mesa encourages the nanowires to orient in a direction parallel with the substrate and perpendicular to the mesa. The nanowires become partially embedded as the metal is deposited. Subsequently, additional electrical contacts can be made to the nanowire.

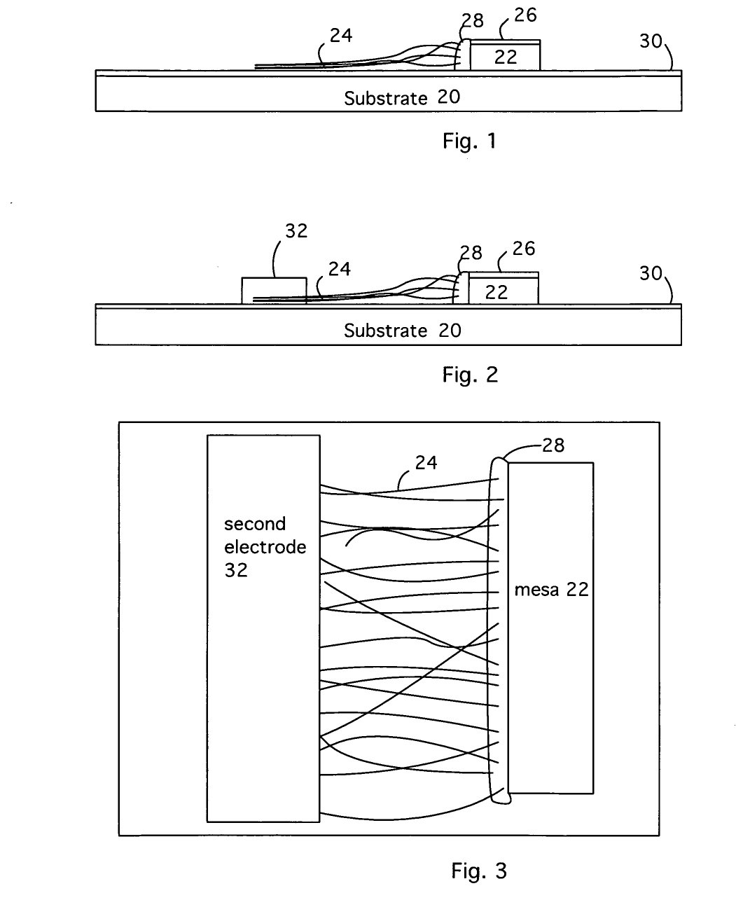

FIG. 1 shows a side view of a nanowire device according to the present invention. The device has a substrate 20, a mesa 22 disposed on the substrate, and nanowires 24. The mesa 22 optionally has an electrically insulating top surface 26. Electrodeposited metal 28 is disposed on a sidewall of the mesa 22. The nanowires are generally parallel with the substrate 20. Optionally, the substrate may have an insulating top surface layer 30.

The substrate 20 can be made of many materials such as semiconductors (e.g. silicon), ceramic, metal, glass, polymers, sapphire, or composites. The present nanowire deposition method can be performed at room temperature, so plastic substrates can be used. Also, the substrate can comprise fully functional circuits, such as CMOS integrated circuits.

The mesa can also be made of many different materials such as metals, doped polysilicon, doped semiconductors, suicides, indium tin oxide, transparent conductors, and the like.

The electrodeposited conductive material 28 (herinafter “metal”) can be any type of metal or alloy or conductive oxide (e.g. indium tin oxide) that can be electrodeposited or electroplated, such as nickel, tin, copper, gold, chromium, zinc, cobalt, indium, indium oxide, tin oxide, aluminum, or titanium. Aluminum and titanium require nonaqueous solutions (e.g. comprising DMSO or ionic liquids) for electroplating, as known in the art. The electrodeposited metal 28 can be selected to form a low resistance ohmic contact with the nanowires (particularly if the nanowires are made of semiconductor material).

The insulating top surface 26 can comprise SiO2, Si3N4, oxides, nitrides, polymers, photoresist or other electrical insulators.

The nanowires can be made of many different materials such as metals, ceramics, polymers, semiconductors carbon and the like. Also, the nanowires can be structured, i.e. the nanowires can have semiconductor junctions (e.g. homo or heterojunctions), core/shell coatings or other features. For example, junctions in the nanowires can be light emitting or light detecting junctions. Also, the nanowires can be doped such that they function as field effect switches or transistors. The nanowires can be made of 2-6 or 3-5 compound semiconductors, GaN, GaInN, ZnO or other semiconductors, for example.

The invention and appended claims are not limited to any particular materials for the substrate 20, mesa 22, insulating surface 26, electrodeposited metal 28 or nanowires 24.

FIG. 2 shows an application of the present nanowire device in which a second electrode 32 is disposed on a free end of the nanowires 24. FIG. 3 shows a top view. The second electrode can be deposited by sputtering or evaporation, and patterned by conventional patterning techniques (e.g. photoresist liftoff). The second electrode 32 and electrodeposited metal 28 (and mesa 22) provide electrical connections to opposite ends of the nanowires 24.

The nanowires 24 can be used for many different applications such as light emitters, light sensors, bio and chemical sensors, electrical switches, as known in the art. For example, chemical coatings on the nanowires can render them sensitive to specific biological or chemical compounds, which are detected by a change in electrical properties (e.g. electrical resistance).

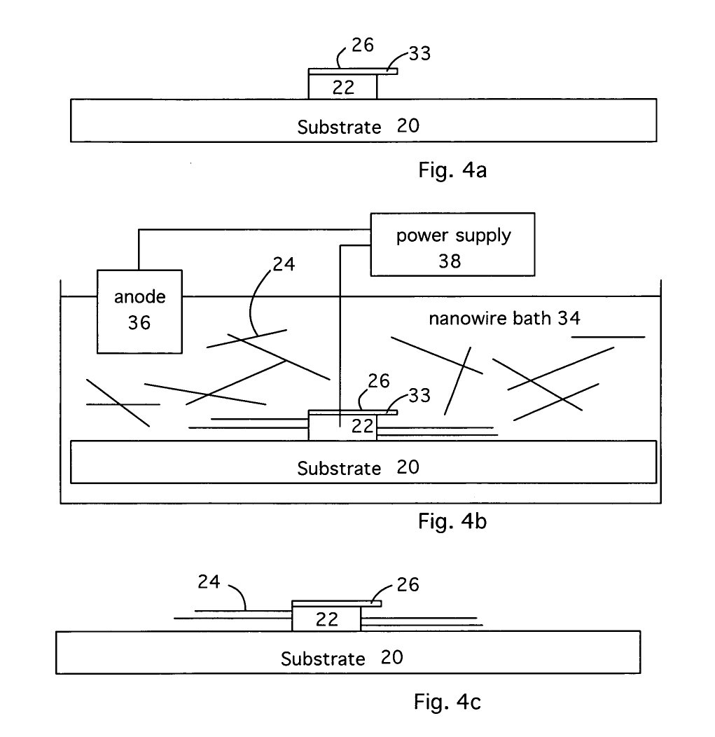

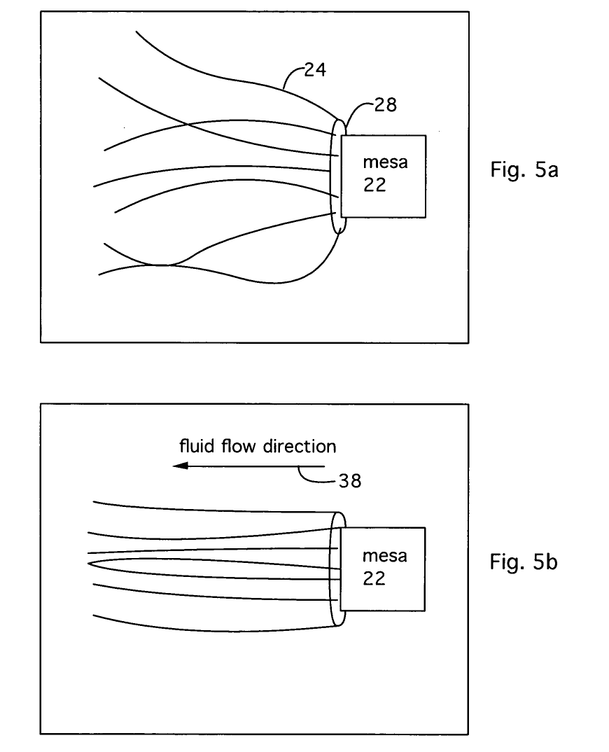

FIGS. 4a-4c illustrate a method for fabricating the present nanowire devices.

FIG. 4a: The mesa 22 is fabricated on the substrate 20. The mesa 22 is provided with an insulating top surface 26. Optionally, the insulating surface 26 can have an overhang 33 extending beyond the mesa 22. The mesa can be 0.1-10 microns tall, for example (typically about 1 micron tall), and can be 1×1 or 100×100 microns wide. The dimensions of the mesa can be chosen by the device designer. Also, it is noted that the mesa 22 does not necessarily have vertical sidewalls. The mesa 22 can have sloped or angled sidewalls, for example within 15, 30, 45, or 60 degrees of vertical.

FIG. 4b: The substrate 20 is immersed in an electrolyte nanowire bath 34 containing nanowires 24. The electrolyte bath 34 contains a solution suitable for electroplating the metal 28. Also, the bath 34 contains a dispersion of nanowires 24. The nanowires can be dispersed by ionic or nonionic surfactants such as benzalkonium chloride, cetyltrimethylammonium bromide (CTAB), surfynol series surfactants, block copolymers, polyvinyl alcohol, siloxanes, and polyoxyethylenes, or other surfactants. A power supply 38 applies voltage between the mesa 22 and an anode 36 such that metal is electrodeposited on sidewalls of the mesa 22. Nanowires 24 are incorporated into the growing metal film 28 and become partially embedded as the film grows. The nanowires will tend to be aligned perpendicularly to the metal film 28, presumably by an electric field in the depletion layer surrounding the mesa 22. Also, an overhang 33 can help to align the nanowires parallel to the substrate 20.

Without wishing to limit the invention to a particular theory, it is believed that nanowires will tend to be electrophoretically oriented by the electric field within the diffusion/boundary layer next to the mesa sidewall. For slightly conductive nanowires having a polarizability greater than the electrolyte in the diffusion layer, the electric field will tend to orient the nanowires perpendicularly to the cathode surface. It is expected that nanowires having a length that is less than about 2× the diffusion layer thickness will tend to be more effectively oriented.

It is noted that many different electroplating methods can be used to deposit the metal 28 and the nanowires 24. For example, DC plating, pulsed DC plating, anodic (reversed) pulsed plating and other plating methods can be used. Also, AC voltages can be combined with the DC plating voltage. For example, AC voltages with frequencies in the range of about 10-200 khz can be used. The present invention is not limited in the types of electrical signals that can be used to provide electrodeposition and nanowire attraction and alignment with the mesa.

FIG. 4c: The substrate is removed from the bath 34, and excess bath liquid and nanowires are rinsed away. Additional processing steps can be used to further align the nanowires 24 and provide electrical connections or coatings to the nanowires.

For example, fluid flow can be used to further align the nanowires. FIG. 5a shows a top view of a nanowire device after nanowires 24 are attached to the mesa 22 by electroplating. The nanowires are only roughly aligned. After nanowire attachment, liquid is flowed over the substrate in direction indicated by arrow 38 in FIG. 5b. The fluid flow helps to improve the alignment of the nanowires. The fluid can be water, alcohol or any other fluid known for the purpose of aligning nanowires.

The combination of electrodeposition and fluid flow alignment results in both orientation (rotational orientation) and positioning of the nanowires. The nanowire ends are pinned by embedding the metal 289, and the fluid flow helps to improve the alignment. In this way, the present invention provides nanowire positioning suitable for fabricating nanowire devices.

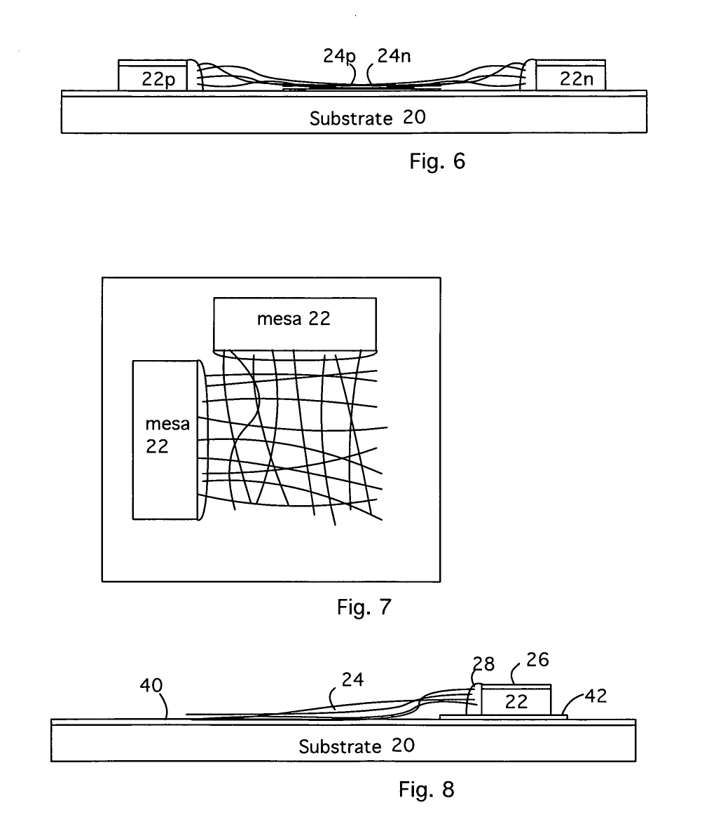

FIG. 6 shows another embodiment in which two mesas 22p 22n are used for depositing p-type nanowires 24p and n-type nanowires 24n, respectively. The nanowires 24n 24p are in contact and generally parallel, forming p-n junctions. Junction formation can be encouraged by an annealing step. The p-n junctions may be light emitting diode junctions or light sensitive junctions for example. Of course, the p-type and n-type nanowires are deposited in two different electroplating steps using two different baths. One bath contains n-type nanowires, and one bath contains p-type nanowires. FIG. 7 shows another embodiment in which two mesas are orthogonal to one another, and thereby tend to create nanowires that intersect perpendicularly.

FIG. 8 shows another embodiment in which a semiconductor layer 40 is disposed under the mesa 22. The mesa 22 is electrically isolated from the semiconductor layer 40 by an electrically insulating layer 42 (e.g. SiO2). In this device, nanowires 24 and the layer 40 form a junction at the point of contact. The junction can be a light emitting or light sensing junction, for example.

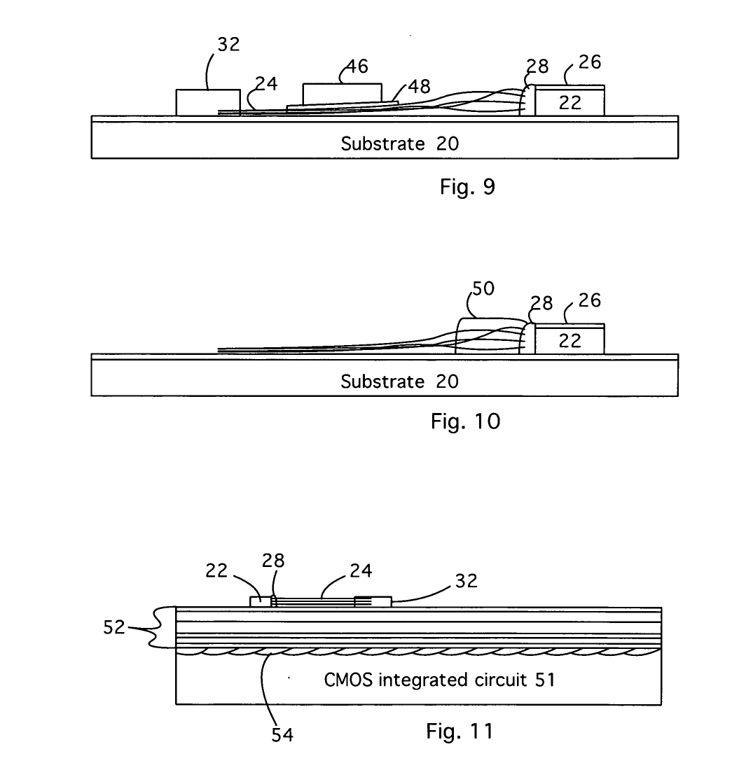

FIG. 9 shows another embodiment comprising a nanowire field effect transistor. A gate insulator layer 48 is disposed between the nanowires 24 and a gate electrode. Mesa 22 and second electrode 32 are the source and drain contacts. Optionally, the gate insulator 48 and gate electrode 46 can extend the entire distance between the second electrode 32 and the mesa 22. Optionally, the substrate functions as a gate electrode, as known in the art.

FIG. 10 shows another embodiment in which a metal bridge contact 50 is disposed in contact with the nanowires and electrodeposited metal 28. The bridge contact 50 provides low resistance electrical contact (e.g. ohmic contact) between the nanowire and the mesa 22. The bridge contact 50 may be beneficial in some devices where it is not possible to provide a low resistance electrical contact to the nanowire with an electroplated metal that is compatible with the nanowire material. For example, aluminum and titanium are sometimes used to create an ohmic contact to semiconductors, but it may not be practical or possible to electroplate aluminum or titanium. In this case, the electroplated metal 28 can comprise a metal that does not form a good electrical contact with the nanowire (e.g. tin or copper), and the bridge contact 50 can be made of aluminum. The bridge contact 50 can be deposited and patterned by conventional techniques such as sputtering or evaporation and photoresist liftoff, for example. The bridge contact 50 can be made of the same material as the second electrode 32 and can be made in the same deposition and patterning steps as the second electrode 32.

FIG. 11 shows another embodiment in which the mesa 22 and nanowires 24 are deposited on a CMOS integrated circuit 51 having CMOS devices 54. In this case, the mesa 22 and second electrode 32 can be sputter deposited or evaporated metal. The circuit 51 has wiring layers 52. The mesa 22 and second electrode 32 are electrically connected to wires (not shown) in the wiring layer 52 so that the nanowires are electrically connected to CMOS devices. The nanowires 24 can provide optoelectronic functionality (e.g. light emission or detection) for optical interconnects, for example. Also, the nanowires can provide electronic functions such as switching, oscillating or signal processing functions. Also, it is noted that the mesa 22, nanowires 24 and second electrode 32 can be disposed within or under the wiring layers 52.

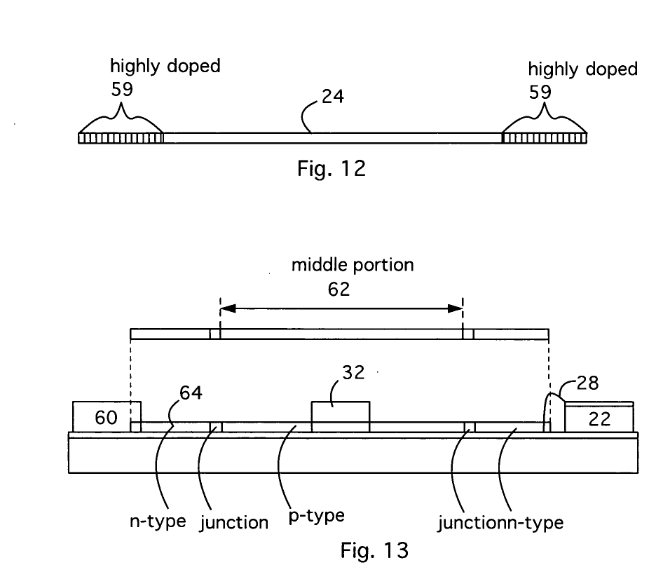

FIG. 12 shows a nanowire 24 with highly doped ends 59 that can be used in the present invention. The highly doped ends facilitate good electrical contact with the electrodeposited metal 28 and the second electrode 32.

FIG. 13 shows an embodiment in which the nanowire has a symmetrical N-P-N structure, with two P-N junctions. Of course, in the present electroplating deposition method, nanowires will have a random polarity because proper orientation cannot be selected. This can create problems in devices that require nanowires with a certain polarity (e.g. with an n-type end connected to the mesa and a p-type end connected to the second electrode 32). To overcome this issue, the nanowires can be fabricated with a symmetrical structure, as shown. The second electrode 32 can then be deposited in the middle portion 62 of the symmetrical nanowire. Optionally, a third electrode 60 can be deposited on the free end 64 of the nanowire to create another junction device between the second and third electrodes.

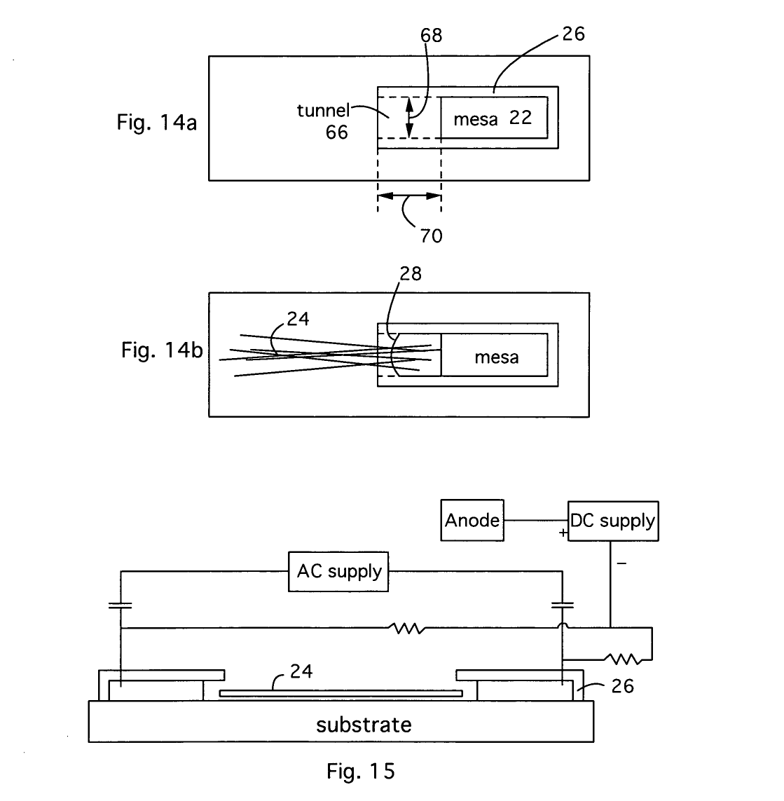

FIGS. 14a and 14b illustrate another embodiment in which the top surface insulator 26 forms a tunnel 66 for the nanowires 24. The tunnel 66 has a width 68 and a length 70. The width and length can be selected for specific applications, or to help align and orient the nanowires 24. The electroplated metal 28 may be contained within the tunnel 66.

FIG. 15 shows an embodiment in which an AC voltage is applied between two spaced-apart mesas. The mesas are also connected to a DC power supply that controls electrodeposition. The AC voltage tends to help align the nanowire, which is locked into place by electrodeposition by the DC current.

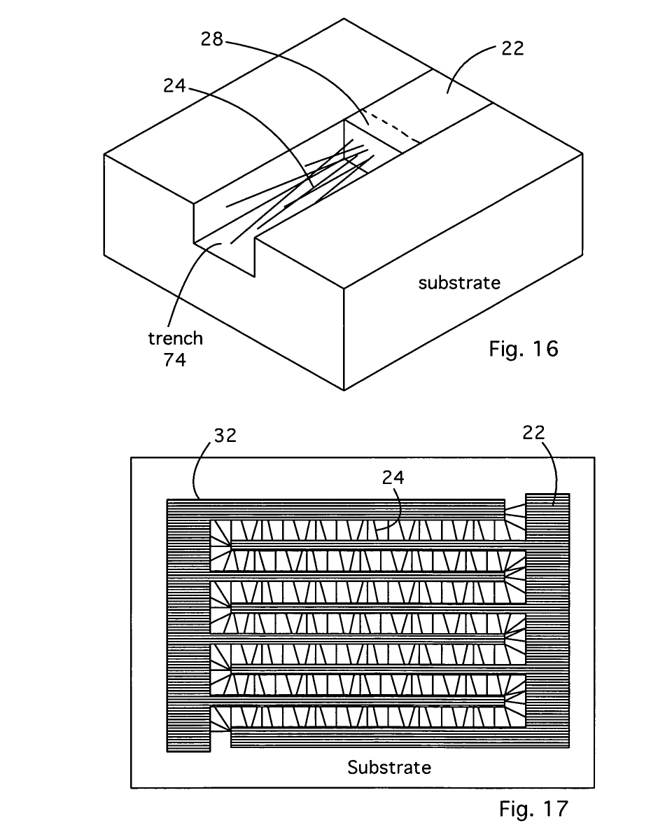

FIG. 16 shows another embodiment in which the mesa 22 is disposed in a trench 74. The nanowires 24 are also disposed in the trench 74. The embodiment of FIG. 16 is within the scope of the appended claims.

FIG. 17 shows a top view of an embodiment in which the mesa 22 and second electrode 32 are interdigitated.

Optionally, the electroplating bath 34 can include brighteners, suppressors and levelers to discourage metal deposition on the nanowires. In embodiments where nanowires do not form a low resistance ohmic contact with the electrodeposited metal, this may not be a concern. For example, if the nanowire and the electroplated metal form a Schottky junction, then current flow into the nanowire will be blocked, thereby inhibiting the deposition of metal onto the nanowire.

Optionally, the mesa 22 does not have an electrically insulating top surface 26. In this case, nanowires deposited on the top surface can be removed by masking the entire substrate, and then planarizing the top surface of the mesa.

The present invention can be used to create a multitude of different kinds of electronic, optical and sensor devices. For example, the present invention can be used to fabricate the following:

Flat panel displays: deposited nanowires can be used to form switching devices in flat panel displays on plastic, glass or flexible substrates. The switching devices can be used to for active matrix control of an LED, LCD or other type of display, as known in the art.

Imaging devices: deposited nanowires can be used to form arrays of sensitive light detectors on plastic, glass or flexible substrates. Large arrays of mesas can be used to create large arrays of light sensitive pixels.

Optical interconnects: deposited nanowires can be used to provide light sensors or light emitters for optical communication between integrated circuits. Also, nanowires can be deposited on fiber optic or optical microbench devices.

Chemical sensors: Deposited nanowires can be provided with chemically selective coatings to render them sensitive to specific chemical or biological materials.

Switching devices, oscillators, signal processing devices: Deposited nanowires can be incorporated into CMOS or other kinds of integrated circuits to provide novel electrical functions.

The present invention and appended claims are not limited to any particular types of devices or functions. The present invention provides a nanowire deposition method and a nanowire device structure that can be applied to fabricate any different kinds of nanowire devices. The present invention and appended claims cover all the disclosed uses of deposited nanowires.

It will be clear to one skilled in the art that the above embodiments may be altered in many ways without departing from the scope of the invention. Accordingly, the scope of the invention should be determined by the following claims and their legal equivalents.

What is claimed is:

1. A method for depositing nanowires on a substrate, comprising the steps of:
forming a mesa on the substrate, wherein the mesa has a conductive sidewall;
immersing the conductive sidewall in an electrodeposition bath containing nanowires;
electrodepositing electrically conductive material onto the mesa sidewall, and simultaneously, partially embedding a nanowire in the electrically conductive material.

2. The method of claim 1 further comprising the step of orienting the nanowire by flowing liquid over the nanowire.

3. The method of claim 1 further comprising the step of depositing a second electrode spaced apart from the mesa, and in electrical contact with the nanowire.

4. The method of claim 1 further comprising the step of depositing a bridge contact making electrical contact to the nanowire and the electrically conductive material or the mesa.

5. The method of claim 1 further comprising the step of applying an AC voltage to the mesa during the electrodeposition step.

6. The method of claim 1 further comprising the step of depositing a gate insulator and a gate electrode on the nanowire.

7. The method of claim 1 wherein the mesa has an insulating layer on a top surface

8. A nanowire device, comprising:
a substrate;
a mesa disposed on the substrate, wherein the mesa has an electrically conductive sidewall;
an electrically conductive material disposed on the mesa sidewall;
a. nanowire partially embedded in the conductive material and extending from the conductive material.

9. The nanowire device of claim 8 wherein the mesa has an electrically insulating top surface.

10. The nanowire device of claim 8 wherein the conductive material has surface features characteristic of an electroplating process.

11. The nanowire device of claim 8 wherein the nanowire is disposed approximately parallel with a surface of the substrate.

12. The nanowire device of claim 8 further comprising a second electrode spaced apart from the mesa, in electrical contact with the nanowire.

13. The nanowire device of claim 8 wherein the nanowire is a light emitter or light detector.

14. The nanowire device of claim 8 wherein the substrate comprises an integrated circuit.

15. The nanowire device of claim 8 further comprising a gate electrode disposed on or under the nanowire.

16. The nanowire device of claim 8 further comprising a bridge electrode electrically connected to the nanowire and to the conductive material or mesa.

17. The nanowire device of claim 8 further comprising a tunnel extending from the sidewall, wherein the nanowire is disposed in the tunnel.

18. The nanowire device of claim 8 wherein the sidewall is angled at least 30 degrees from the substrate surface.

19. A nanowire device, comprising:
a substrate;
a mesa disposed on the substrate, wherein the mesa has an electrically conductive sidewall, and an electrically insulating top surface;
a metal disposed on the mesa sidewall;
a semiconductor nanowire partially embedded in the metal and extending from the metal in a direction parallel with a surface of the substrate.
